(19) United States
(12) Patent Application Publication
(10) Pub. No.: US 2019/0363298 A1
(43) Pub. Date: Nov. 28, 2019

(54) DISPLAY DEVICE

(71) Applicant: KABUSHIKI KAISHA TOKAI RIKA DENKI SEISAKUSHO, Aichi (JP)

(72) Inventors: Jun KAWAMORI, Aichi (JP); Ryoko NAKANO, Aichi (JP)

(21) Appl. No.: 16/479,383

(22) PCT Filed: Jan. 23, 2018
(86) PCT No.: PCT/JP2018/002015

§ 371 Date: Jul. 19, 2019

(30) Foreign Application Priority Data
Feb. 8, 2017 (JP) 2017-021184

(51) Int. Cl. H01L 51/52; H01L 27/32; G09F 9/30

(52) U.S. Cl. CPC H01L 51/5271; H01L 27/32; B60K 35/00; H01L 51/5234; G09F 9/30; H01L 51/5206

(57) ABSTRACT

A display device includes a transparent organic EL element, and a base material that is arranged facing the transparent organic EL element and reflects incident light. A reflective surface of the base material is formed as a decorative surface. Decorative designs formed on the decorative surface are presented at a lower position than information subject to light-emitting display via the transparent organic EL element.

### CROSS-REFERENCE TO RELATED APPLICATIONS

The present application claims the priority of Japanese patent application. No. 2017-021184 filed on Feb. 8, 2017, the entire contents of which are herein incorporated by reference.

### TECHNICAL FIELD

The present invention relates to a display device.

### BACKGROUND ART

A display device provided with a display portion which is constructed from an EL display and is provided on a shift knob arranged on the top of a shift lever of automobile, etc., is one example of display device using an organic EL (electroluminescence) element (see, e.g., JP 2007/137221 A).

The display portion described in JP 2007/137221A has an organic EL element formed by laminating a transparent electrode layer, an organic layer including a light-emitting layer and a reflective electrode layer on a surface of a transparent substrate.

The organic EL element emits light so that letters or symbols indicating the current shift position of the shift lever is displayed. Therefore, the letters or symbols displayed by light emitted from the organic EL element is seen through the back surface of the transparent substrate.

### CITATION LIST

### Patent Literature

JP 2007/137221 A

### SUMMARY OF INVENTION

### Technical Problem

The display device disclosed in JP 2007/137221 A is configured to simply display letters or symbols by light emitted from the organic EL element and thus does not have much decorative effect. Therefore, there is a demand for a display device which can provide not only display but also the decorative effect by using an organic EL element.

It is an object of the invention to provide a display device which has a function of providing an information display effect as well as a decorative effect.

### Solution to Problem

A display device according to an embodiment of the invention is configured as defined in [1] to [7] below.

[1] A display device, comprising: a transparent organic EL element; and a base material that is arranged facing the transparent organic EL element and reflects incident light, wherein a reflective surface of the base material is formed as a decorative surface, and decorative designs formed on the decorative surface are presented at a lower position than information subject to light-emitting display via the transparent organic EL element.

[2] The display device according to [1], wherein the transparent organic EL element comprises a transparent anode, a transparent cathode and a transparent organic light-emitting layer arranged between the transparent anode and the transparent cathode, and light produced from the transparent organic light-emitting layer exits out through the transparent anode and the transparent cathode.

[3] The display device according to [1] or [2], wherein the transparent organic EL element comprises an information display portion for displaying information and a pattern display portion for displaying a pattern.

[4] The display device according to any one of [1] to [3], wherein the decorative design comprises a recessed polyhedron with a plurality of inclined faces, and the polyhedron is arranged in the form of a two-dimensional array.

[5] The display device according to [4], wherein the polyhedron comprises a triangular pyramid comprising three inclined triangular faces as the plurality of inclined faces.

[6] The display device according to [4], wherein the polyhedron comprises a square pyramid comprising four inclined triangular faces as the plurality of inclined faces.

[7] The display device according to [4], wherein the polyhedron comprises a square frustum comprising four inclined trapezoidal faces as the plurality of inclined faces that form a square base.

### Advantageous Effects of Invention

According to an embodiment of the invention, it is possible to provide a display device which has a function of providing an information display effect as well as a decorative effect by taking advantage of the characteristics of a two surface-emitting transparent organic EL element.

### BRIEF DESCRIPTION OF DRAWINGS

FIG. 1 is an exploded perspective view showing a display device in an embodiment or the present invention.

FIG. 2A is a plan view showing a base material constituting a portion of the display device in the embodiment.

FIG. 2B is a cross sectional view taken along a line in FIG. 2A and viewed in an arrow direction.

FIG. 3 is a plan view showing the form of display when the display device in the embodiment provides display by light emission.

FIG. 4A is a plan view showing a first modification of the base material.

FIG. 4B is a cross sectional view taken along a line IVb-IVb in FIG. 4A and viewed in an arrow direction.

FIG. 5 is a plan view showing the firm of display when the display device having the base material in the first modification provides display by light emission.

FIG. 6A is a plan view showing a second modification of the base material.

FIG. 6B is a cross sectional view taken along a line VIb-VIb in FIG. 6A and viewed in an arrow direction.

FIG. 7 is a plan view showing the form of display when the display device having the base material in the second modification provides display by light emission.

### DESCRIPTION OF EMBODIMENTS

An embodiment of a display device of the invention will be described below in reference to the appended drawings. The drawings according to the embodiment are exaggerated in terms of aspect ratio, etc., for the purpose of facilitating the description of the configuration.

### General Configuration of a Display Device

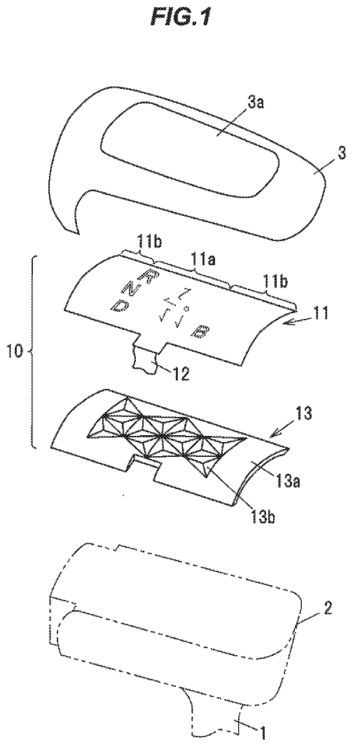

In FIG. 1, a shift lever used for gear changing operation of a vehicle transmission is denoted by the reference numeral 1. The shift lever 1 is composed of a shift knob 2 and a knob cover 3 covering the shift knob 2. The knob cover 3 has a transparent display window 3a which allows position information of the shift lever 1 and decorative design, etc., to be seen.

A display device 10, which is a characteristic part in the present embodiment, is housed in a space between the shift knob 2 and the knob cover 3. The display device 10 is provided with a transparent organic EL element 11 capable of emitting light in various colors and a base material 13 arranged facing the back surface of the transparent organic EL element 11. The back surface of the base material 13 is placed in contact with the top of the shift knob 2.

The transparent organic EL element 11 is configured as a first display portion which emits light to display information or pattern, etc. The base material 13 is configured as a reflector which reflects light incident from the vehicle interior, the outside and the transparent organic EL element 11. The base material 13 is curved so as to bulge out toward the front surface side.

### Configuration of the Transparent Organic EL Element

The transparent organic EL element 11, which is the first display portion of the display device 10, has a transparent anode as a first transparent electrode, a transparent cathode as a second transparent electrode, and a transparent organic light-emitting layer arranged between the transparent anode and the transparent cathode.

The transparent organic EL element 11 is a flexible, two surface-emitting transparent organic EL element which is configured such that light produced from the transparent organic light-emitting layer can be extracted to the outside on both the transparent anode side and the transparent cathode side. The transparent organic EL element 11 is transparent when turned off (when not emitting light), and is configure to have the transparent organic light-emitting layer formed using light-emitting materials with different emission colors and thereby emit light in different colors when turned on (when emitting light).

The transparent organic EL element 11 is provided with a flexible substrate 12 which supplies power to the transparent organic light-emitting layer through the transparent anode and the transparent cathode. By applying DC power between the transparent anode and the transparent cathode via the flexible substrate 12, holes from the transparent anode and electrons from the transparent cathode are injected into the transparent organic light-emitting layer.

Energy released from the recombination of the holes injected from the transparent anode and the electrons injected from the transparent cathode inside the transparent organic light-emitting layer excites the organic light-emitting materials in the transparent organic light-emitting layer. The transparent organic light-emitting layer emits light when the excited organic light-emitting materials return back to the ground state.

When the transparent organic EL element 11 is off, information or pattern, etc., displayed by emitting light from the transparent organic EL element 11 does not appear since the transparent organic light-emitting layer does not emit light. When the transparent organic EL element 11 is on, light produced from the transparent organic light-emitting layer exits out through both the transparent anode and the transparent cathode.

Light, which exits out through the transparent cathode arranged on a knob cover-facing surface of the transparent organic EL element 11, is visible through the display window 3a of the knob cover 3 in such a manner that information or pattern, etc., produced by the transparent organic EL element 11 is shown.

As shown in FIGS. 1 and 3, the transparent organic EL element 11 has an information display portion 11a on which information such as letters, numbers, symbols or marks are displayed by light emission, and a pattern display portion 11b on which pattern is displayed by light emission.

The information display portion 11a in the example shown in the drawings is formed as a position display portion on which the shift position of the shift lever 1 is displayed. On the other hand, the pattern display portion 11b is formed as an image display portion in which polka dots are dispersed in a linear or belt-shaped array.

The information display portion 11a for displaying information by light emitted from the transparent organic EL element 11 is configured to display the symbol indicating information about the shift position of the shift lever 1, i.e., Drive (D), Neutral (N), Reverse (R), home position and regenerative brake (B), by light emission. When the transparent organic EL element 11 is on, the information indicating such shift positions is provided by light emission in any color such as white, green or red. The polka dot pattern on the pattern display portion 11b is provided by white light emission when the transparent organic EL element 11 is on.

Meanwhile, light, which exits out through the transparent anode arranged on the knob cover-facing surface of the transparent organic EL element 11, illuminates the front surface of the base material 13 which is arranged facing the back surface of the transparent organic EL element 11. The illuminating light is visible through the display window 3a of the knob cover 3.

To form the transparent organic EL element 11, any known structure and material, etc., can be used without specific limitation.

### Configuration of the Base Material

With the display device 10 as described above, information or patterns, etc., displayed by emitting light from the transparent organic EL element 11 becomes highly visible. However, only with high visibility of information or patterns, etc., it is difficult to provide the stereoscopic effect or to give perception of depth and it is thus difficult to provide high design quality and give luxurious feel.

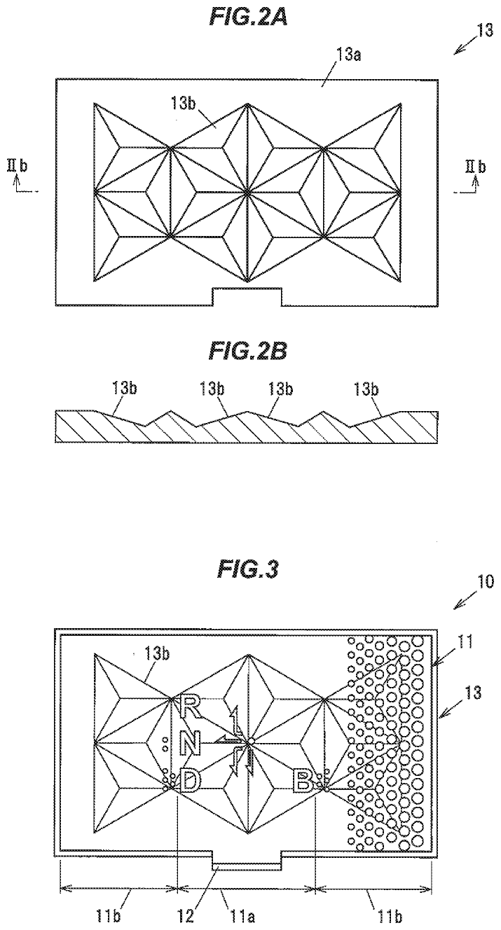

As shown in FIGS. 1, 2A and 2B, the display device 10 in the present embodiment is configured such that a reflective surface 13a of the base material 13 for reflecting light incident from the vehicle interior, the outside and the transparent organic EL element 11 is used as the decorative surface, and the display device 10 thus has a second display on which decorative designs 13b formed on the decorative surface are displayed, in addition to the first display portion for displaying information or pattern, etc., by emitting light from the transparent organic EL element 11.

On the reflective surface 13a which is a decorative surface of the base material 13 as the second display portion, the decorative designs 13b engraved in recessed triangular pyramid shape having three inclined triangular faces are formed as polyhedra. The decorative designs 13b are arranged in the form of a two-dimensional array on the reflective surface 13a which faces the back surface of the transparent organic EL element 11.

When the transparent organic EL element 11 is off, the second display portion to be illuminated by the transparent organic EL element 11 shines brightly since external light incident from the vehicle interior and the outside is reflected on the recessed-triangular pyramid-shaped decorative designs 13b of the base material 13. Since reflection light reflected by the recessed-triangular pyramid-shaped decorative designs 13b is visible through the display window 3a of the knob cover 3, the reflection light is used as presentation light to provide stage effect.

As shown in FIGS. 1 and 3, the base material 13 is configured to be arranged underneath the transparent organic EL element 11. Due to such configuration, information or pattern, etc., displayed by light exiting out through transparent cathode of the transparent organic EL element 11 can be seen through the display window 3a of the knob cover 3 when the transparent organic EL element 11 is on.

On the other hand, light exiting out through the transparent anode of the transparent organic EL element 11 is reflected by the recessed-triangular pyramid-shaped decorative designs 13b formed on the reflective surface 13a as the decorative surface of the base material 13 which thereby shines brightly. The recessed-triangular pyramid-shaped decorative designs 13b are displayed three-dimensionally and clearly underneath the information and patterns, etc., displayed on the transparent organic EL element 11.

Plural recessed-triangular pyramid-shaped decorative designs 13b of the base material 13 are three-dimensionally visible through the display window 3a of the knob cover 3 as if the decorative designs 13b hang in the air. It is thereby possible to provide the stereoscopic effect or to give perception of depth, thereby enhancing luxurious feel.

### Other Configurations of the Base Material

Although the reflective surface 13a of the base material 13 configured as described above is a three-dimensional structure having recessed triangular pyramids, various three-dimensional structures can be used without specific limitation. The shape and size, etc., of the decorative design 13b can be appropriately changed as long as it is a configuration not hindering brightness, etc.

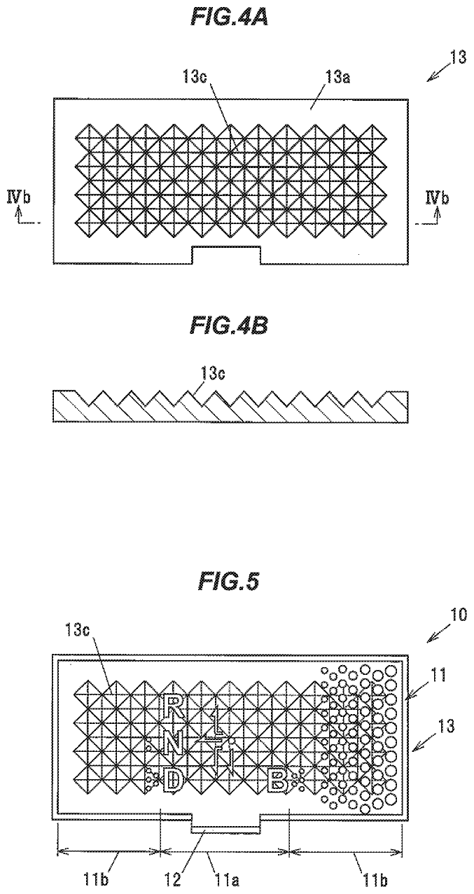

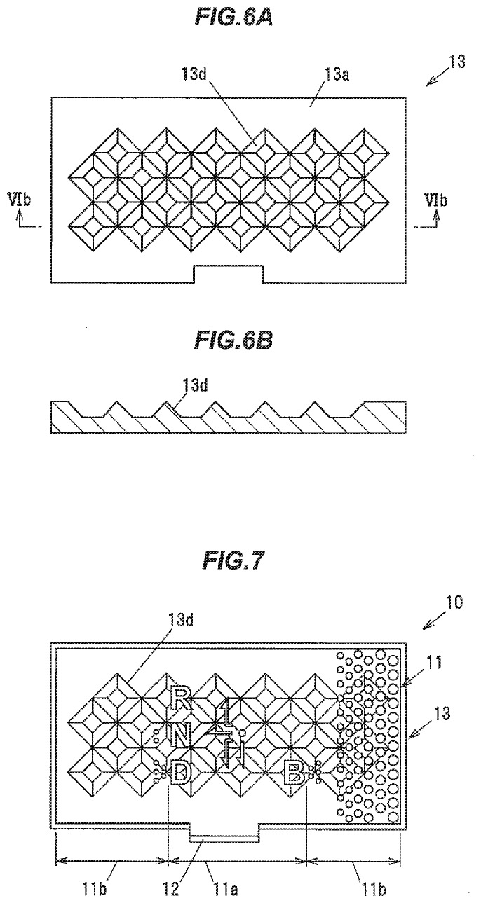

The three-dimensional structure on the reflective surface 13a can be composed of polyhedra formed in recessed square pyramid shape or polyhedra formed in recessed square frustum shape, as shown in FIGS. 4A and 6A.

Decorative designs 13c engraved in recessed square pyramid shape having four inclined triangular faces are formed on the reflective surface 13a which is a decorative surface of the base material 13, as shown in FIGS. 4A and 4B. The decorative designs 13c are arranged in the form of a two-dimensional array on the reflective surface 13a which faces the back surface of the transparent organic EL element 11.

When the transparent organic EL element 11 is emitting light or is off, light incident from the vehicle interior, the outside and the transparent organic EL element 11 is reflected on the recessed-square pyramid-shaped decorative designs 13c of the base material 13 which thereby shines brightly. Due to having the bright shining effect, reflection light reflected by the recessed-square pyramid-shaped decorative designs 13c can be used as presentation light.

As shown in FIG. 5, the recessed-square pyramid-shaped decorative designs 13c are displayed three-dimensionally and clearly underneath the information and patterns, etc., displayed by light emitted from the transparent organic EL element it Reflection light reflected by the recessed-square pyramid-shaped decorative designs 13c is visible through the display window 3a of the knob cover 3, and this provides the stereoscopic effect or to give perception of depth.

Decorative designs 13d engraved in recessed square frustum shape having four inclined trapezoidal faces forming a square base are formed on the reflective surface 13a which is a decorative surface of the base material 13, as shown in FIGS. 6A and 6B, The decorative designs 13d are arranged in the form of a two-dimensional array on the reflective surface 13a which faces the back surface of the transparent organic EL element 11.

When the transparent organic EL element 11 is emitting light or is off, light incident from the vehicle interior, the outside and the transparent organic EL element 11 is reflected on the recessed-square frustum-shaped decorative designs 13d of the base material 13 which thereby shines brightly. Due to having the bright shining effect, reflection light reflected by the recessed-square frustum-shaped decorative designs 13d can be used as presentation light.

As shown in NG 7, the recessed-square frustum-shaped decorative designs 13d are displayed three-dimensionally and clearly underneath. the information and patterns, etc., displayed by light emitted from the transparent organic EL element 11. Reflection light reflected by the recessed-square frustum-shaped decorative designs 13d is visible through the display window 3a of the knob cover 3, and this provides the stereoscopic effect or to give perception of depth.

To form the base material 13, any known structure and material, etc., can be used without specific limitation. In addition, as surface treatment of the base material 13, a reflective metal layer can be deposited as a light reflecting layer on the reflective surface 13a which faces the back surface of the transparent organic EL element 11. Furthermore, silver, etc., can be applied to the reflective surface 13a.

By treating the surface of the base material 13, it is possible to obtain the decorative design effect such as repeated reflection by the decorative designs 13b, 13c, 13d of the base material 13. It is also possible to obtain the decorative design effect by change in light color produced by the transparent organic EL element 11. An innovative decorative design effect can be also obtained through the display window 3a of the knob cover 3 having a flat surface.

### Effects of the Embodiment

The display device 10 described above has a configuration in which the position of the base material 13 as the second display portion for displaying the decorative designs 13b, 13c, 13d is lower than the position of the transparent organic EL element 11 as the first display portion for displaying information or pattern, etc. As a result, the recess-shaped decorative designs 13b, 13c, 13d of the base material 13 can be displayed three-dimensionally and clearly underneath the position of information and patterns, etc., displayed on the transparent organic EL element 11. In addition to such effect, the following effects are obtained.

By three-dimensionally engraving the reflective surface 13a of the base material 13 and using the engraved reflective surface 13a as a decorative surface, it is possible to effectively take advantage of the characteristics of a two surface-emitting transparent organic EL element 11.

It is possible to realize the information display effect and the decorative effect during light emission as well as the decorative effect during no light emission without losing clarity when the transparent organic EL element 11 is emitting light or is off.

In is possible to increase three-dimensionally displayable depictions by engraving on the base material 13 in combination with graphical display on the transparent organic EL element 11.

It is possible to show three-dimensional transparent display without impairing visual quality during light emission as well as during no light emission.

The device can provide the information display effect and the decorative effect and also can function as a lighting.

The display device 10 configured as described above is applicable as a display device of various on-board, mobile and household devices.

As understood from the description above, although the representative embodiment, the modifications and the examples shown in the drawings of the invention have been described as examples, the invention according to claims is not to be limited to the embodiment, the modifications and the examples shown in the drawings. Therefore, it should be noted that all combinations of the features described in the embodiment, the modifications and the example shown in the drawings are not necessary to solve the problem of the invention.

### REFERENCE SIGNS LIST

10 DISPLAY DEVICE
11 TRANSPARENT ORGANIC EL ELEMENT
11a INFORMATION DISPLAY PORTION
11b PATTERN DISPLAY PORTION
12 FLEXIBLE SUBSTRATE
13 BASE MATERIAL
13a REFLECTIVE SURFACE
13b, 13c, 13d DECORATIVE DESIGN

1. A display device, comprising:
a transparent organic EL element; and
a base material that is arranged facing the transparent organic EL element and reflects incident light,
wherein a reflective surface of the base material is formed as a decorative surface, and
wherein decorative designs formed on the decorative surface are presented at a lower position than information subject to light-emitting display via the transparent organic EL element.

2. The display device according to claim 1, wherein the transparent organic EL element comprises a transparent anode, a transparent cathode and a transparent organic light-emitting layer arranged between the transparent anode and the transparent cathode, and
wherein light produced from the transparent organic light-emitting layer exits out through both the transparent anode and the transparent cathode.

3. The display device according to claim 1, wherein the transparent organic EL element comprises an information display portion for displaying information and a pattern display portion for displaying a pattern.

4. The display device according to claim 1, wherein the decorative design comprises a recessed polyhedron with a plurality of inclined faces, and the polyhedron is arranged in the form of a two-dimensional array.

5. The display device according to claim 4, wherein the polyhedron comprises a triangular pyramid comprising three inclined triangular faces as the plurality of inclined faces.

6. The display device according to claim 4, wherein the polyhedron comprises a square pyramid comprising four inclined triangular faces as the plurality of inclined faces.

7. The display device according to claim 4, wherein the polyhedron comprises a square frustum comprising four inclined trapezoidal faces as the plurality of inclined faces that form a square base.
